(19) United States
(12) Patent Application Publication
(10) Pub. No.: US 2003/0099100 A1
(43) Pub. Date: May 29, 2003

(54) Adaptive module for housings

(76) Inventor: John W. Baker, Hudson, MA (US)

Correspondence Address: LEFFERT JAY & POLGLAZE, P.A., P.O. BOX 581009, MINNEAPOLIS, MN, 55458-1009, US

(21) Appl. No.: 09/995,262

(22) Filed: Nov. 26, 2001

(51) Int. Cl. H05K 7/14; H05K 7/18

(52) U.S. Cl. 361/796

(57) ABSTRACT

An adaptive module for a cable modem termination system housing having a backplane and a card cage that is attachable to the housing is provided. Active and backup first electronic modules are disposed within the card cage and are electrically connected to the backplane. The active and backup first electronic modules are respectively electrically connectable to active and backup second electronic modules disposed within the housing, where the backup first electronic module communicates with the backup second electronic module when there is a failure within the active second electronic module. A switch/relay is disposed within the card cage and is electrically connected to the backplane. The switch/relay is adapted to enable communication between the active first electronic module and the backup second electronic module when there is a failure within the active second electronic module.

### TECHNICAL FIELD

The present invention relates generally to the field of housings for electronics and, in particular, to an adaptive module for housings.

### BACKGROUND

A common method for improving system reliability involves redundancy. This typically involves having active system components and backup system components that duplicate the active system components. The purpose of the backup system components is to take over for the active system components in the event that the active system components fail. In many electronic systems, such as cable modem termination systems (CMTSs), this involves switching from the active system components to the backup system components when the active system components fail.

In the example of cable modem termination systems, many cable modem termination systems include a number of electronic modules that are contained within housings and are plugged into backplanes within the housings. To provide redundancy, some of the electronic modules are used as backup modules. This is typically accomplished using additional components, e.g., for connecting the electronic modules to function as backups, switching to the backup modules, etc. However, this usually requires designing and manufacturing a separate line of larger housings for accommodating the additional components. Moreover, it is often desirable to upgrade non-redundant systems to redundant systems in the field. One problem with this is that the housings for many non-redundant systems are too small to accommodate the additional components. Therefore, the non-redundant system, including the housing, needs to be replaced with a redundant system in a larger housing. Some manufacturers provide for upgrades by housing the non-redundant systems in housings large enough to accommodate the additional components and include the additional components. However, many customers do not require such upgrades and end up paying for larger housings and for additional components that are not needed, as well as higher shipping costs for shipping the larger housings and additional components.

For the reasons stated above, and for other reasons stated below that will become apparent to those skilled in the art upon reading and understanding the present specification, there is a need in the art for mitigating the problems associated with adding additional components to electronic systems, such as cable modem termination systems, for making these systems redundant.

### SUMMARY

The above-mentioned problems with adding additional components to electronic systems to make these systems redundant and other problems are addressed by embodiments of the present invention and will be understood by reading and studying the following specification. Embodiments of the present invention provide an adaptive module for modifying existing housings for containing non-redundant electronic systems, such as the existing housings for non-redundant cable modem termination systems, to add redundancy to the electronic systems. This enables existing non-redundant electronic systems to be upgraded in the field to redundant systems without having to replace the existing housing. Moreover, this eliminates the need for designing and manufacturing a new line of housings for housing redundant systems.

### BRIEF DESCRIPTION OF THE DRAWINGS

FIG. 1 is an exploded perspective view of a housing according to the teachings of the present invention.

FIG. 2 is an exploded side view of the housing of FIG. 1.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

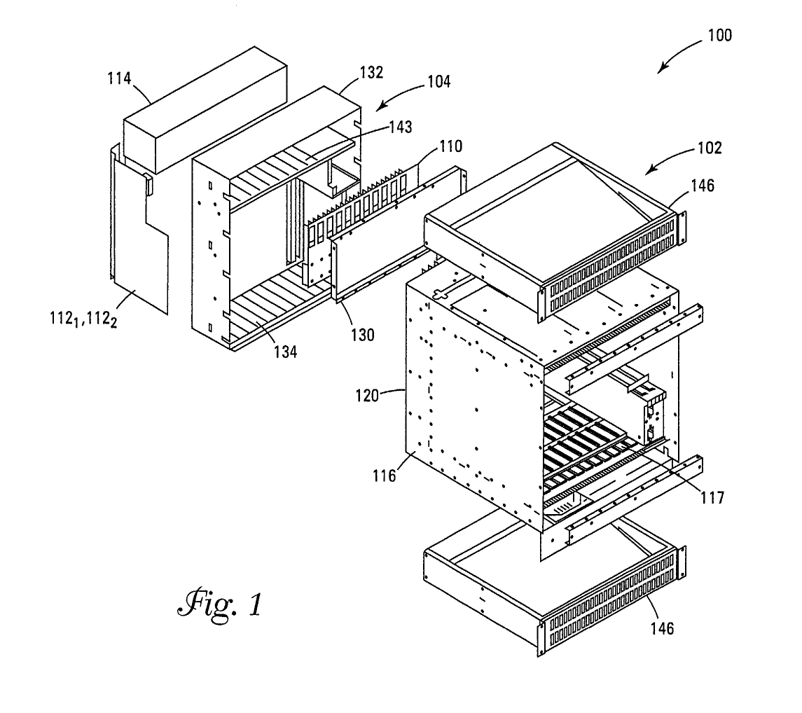

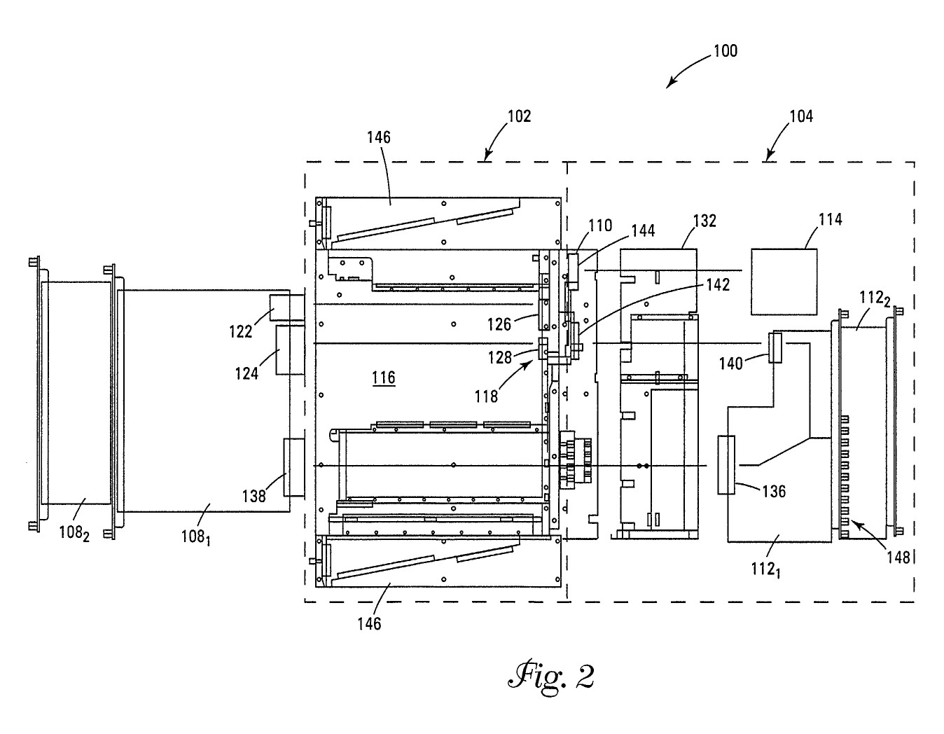

FIGS. 1 and 2 illustrate an embodiment of a housing 100 for an electronic system, such as a cable modem termination system, according to the teachings of the present invention. FIG. 1 is an exploded perspective view, and FIG. 2 is an exploded side view. Housing 100 includes a base module 102 and an adaptive module 104. In one embodiment, base module 102 is a basic housing for a non-redundant electronic system, such as a cable modem termination system, e.g., a non-redundant CUDA 12000 cable modem termination system commercially available from ADC Telecommunications of Eden Prairie, Minn. In another embodiment, adaptive module 104 is added to base module 102 to add redundancy to the electronic system.

In one embodiment, adaptive module 104 is added to a basic housing of a non-redundant cable modem termination system to upgrade the non-redundant cable modem termination system without having to change the basic housing of the non-redundant system. In other embodiments, adaptive module 104 is added to the basic housing of non-redundant cable modem termination systems during manufacturing, enabling redundant cable modem termination systems to be manufactured from the existing basic housings. This eliminates the need for designing and manufacturing a new line of housings for housing redundant systems.

Base module 102 is adapted to house a number of primary electronic modules adapted to transmit and receive signals, e.g., primary electronic modules 108₁ and 108₂ of the electronic system. More particularly, base module 102 includes a card cage 116 having slots 117 for receiving primary electronic modules 108₁ and 108₂. A backplane 118 is secured within card cage 116 adjacent to an end 120 of card cage 116 using fasteners, such as screws, bolts or the like. Each of primary electronic modules 108₁ and 108₂ plugs into backplane 118. For example, connectors 122 and 124 of primary electronic module 1081 respectively connect to connectors 126 and 128 of backplane 118, as shown in FIG. 2. In one embodiment, base module 102 of housing 100 includes plenums 146 for providing directed airflow for cooling the electronic system.

Adaptive module 104 has a backplane 110. In one embodiment, backplane 110 is secured to card cage 116 adjacent to end 120 of card cage 116 so that backplane 110 is spaced from backplane 118 and is parallel to backplane 118. In another embodiment, a cover 130 is disposed between backplane 110 and backplane 118. A card cage 132 of adaptive module 104 is secured to card cage 116 adjacent to end 120 using fasteners, such as screws, bolts, or the like. A number of secondary electronic modules adapted to transmit and receive signals, e.g., secondary electronic modules 112₁ and 112₂, are disposed in slots 134 of card cage 132. Each of secondary electronic modules 112₁ and 112₂ respectively connects to each of primary electronic modules 108₁ and 108₂. In various embodiments, each of secondary electronic modules 112₁ and 112₂ respectively receives signals from and/or transmits signals to each of primary electronic modules 108₁ and 108₂

More specifically, connector 136 of secondary electronic module 112₁ connects to connector 138 of primary electronic module 108₁, as illustrated in FIG. 2. Each of secondary electronic modules 112₁ and 112₂ also connect to backplane 110, e.g., connector 140 of secondary electronic module 112₁ connects to connector 142 of backplane 110. Circuit boards of a switch/relay 114 are disposed in slots 143 of card cage 132. Switch/relay 114 connects to connector 144 of backplane 110. Secondary electronic module 112₁ includes a number of connectors 148 for connecting the electronic system to remote equipment, such as modems or the like. In one embodiment, connectors 148 transmit signals to remote equipment and receive signals from the remote equipment.

In one embodiment, secondary electronic modules 112₁ and 112₂ are respectively active and backup secondary electronic modules, and primary electronic modules 108₁ and 108₂ are identical. Connecting secondary electronic module 112₂ to primary electronic module 108₂ and to backplane 110 connects primary electronic module 108₂ as a backup to primary electronic module 108₁. Switch/relay 114 switches operation from primary electronic module 108₁ to primary electronic module 108₂ in the event a failure occurs within primary electronic module 108₁. In this way, adaptive module 104 adds redundancy to an otherwise non-redundant electronic system.

During operation, secondary electronic module 112₁ receives first signals from primary electronic module 108₁, designated as an active electronic module, and transmits a first portion of the first signals to backplane 110 and a second portion to connectors 148. Backplane 110 transmits the first portion of the first signals to switch/relay 114. If the first signals are okay, e.g., no failures within primary electronic module 108₁, the first portion of the first signals are terminated at switch/relay 114 and the second portion of the first signals are transmitted to remote equipment via connectors 148. Second signals are also received at secondary electronic module 112₁ via connectors 148 from the remote equipment. Secondary electronic module 112₁ transmits a first portion of the second signals to connector 136 and a second portion of the second signals to backplane 110. Backplane 110 transmits the second portion to switch/relay 114, where the second portion is terminated. Connector 136 transmits the first portion of the second signals to primary electronic module 108₁.

In the event of a failure within primary electronic module 108₁, e.g., the first signals received at switch/relay 114 are bad, switch/relay 114 switches to a backup mode. In the backup mode, secondary electronic module 112₂ receives the first signals from primary electronic module 108₂, designated as a backup electronic module. These first signals are the same first signals that secondary electronic module 112₁ received from primary electronic module 108₁ prior to the failure. Secondary electronic module 112₂ transmits the first signals to backplane 110. Backplane 110 transmits the first signals to switch/relay 114. If the first signals are okay, e.g., no failures, switch/relay 114 transmits the first signals back to backplane 110. Backplane 110 transmits the first signals to secondary electronic module 112₁, which outputs the first signals at connectors 148. In switching to the backup mode, switch/relay 114 enables the first signals to be routed from secondary electronic module 112₂ to connectors 148. In the backup mode, secondary electronic module 112₁ provides an interface between primary electronic module 1082 and remote equipment.

During backup mode operation, the second signals received at connectors 148 from the remote equipment are conveyed from secondary electronic module 112₁ to backplane 110. Backplane 110 transmits the second signals to switch/relay 114, which sends the second signals back to backplane 110. Backplane 110 transmits the second signals to secondary electronic module 1122. Secondary electronic module 1122 transmits the second signals to primary electronic module 1082. In switching to the backup mode, switch/relay 114 also enables the second signals to be routed from connectors 148 to secondary electronic module 1122.

In one embodiment, primary electronic modules 108, secondary modules 112, and switch/relay 114 are respectively the CMTS transceivers, interface adapters, and switch module of U.S. patent application Ser. No. ______ (Attorney Docket No. 100.361US01) filed Nov. 26, 2001, commonly assigned, which application is incorporated herein by reference.

### CONCLUSION

Embodiments of the present invention have been described. The embodiments provide an adaptive module for modifying existing housings for containing non-redundant electronic systems, such as the existing housings for non-redundant cable modem termination systems, to add redundancy to the electronic systems. This enables existing non-redundant electronic systems to be upgraded in the field to redundant systems without having to replace the existing housing. Moreover, this eliminates the need for designing and manufacturing a new line of housings for housing redundant systems.

Although specific embodiments have been illustrated and described in this specification, it will be appreciated by those of ordinary skill in the art that any arrangement that is calculated to achieve the same purpose may be substituted for the specific embodiment shown. This application is intended to cover any adaptations or variations of the present invention. For example, backplane 110 can be secured within card cage 132 instead of being secured to card cage 116.

What is claimed is:

1. An adaptive module for a housing for a cable modem termination system, the module comprising:
a backplane;
a card cage attachable to the housing;
an active first electronic module disposed within the card cage and electrically connected to the backplane, the active first electronic module electrically connectable to an active second electronic module disposed within the housing for communicating with the active second electronic module;
a backup first electronic module disposed within the card cage and electrically connected to the backplane, the backup first electronic module electrically connectable to a backup second electronic module disposed within the housing for communicating with the backup second electronic module when there is a failure within the active second electronic module; and
a switch/relay disposed within the card cage and electrically connected to the backplane, the switch/relay adapted to enable communication between the active first electronic module and the backup second electronic module when there is a failure within the active second electronic module.

2. The adaptive module of claim 1, wherein the active first electronic module comprises a plurality of connectors connectable to remote equipment.

3. The adaptive module of claim 1, wherein the switch/relay comprises a plurality of circuit boards.

4. The adaptive module of claim 1, wherein the backplane is attachable to the housing.

5. The adaptive module of claim 1, wherein the backplane is disposed within the card cage.

6. A housing for an electronic system:
a first module;
a first backplane disposed within the first module;
first and second electronic modules disposed within the first module, each of the first and second electronic modules electrically connected to the first backplane;
a second module attached to the first module, the second module comprising a second backplane;
a third electronic module disposed within the second module, the third electronic module electrically connected to the first electronic module and to the second backplane;
a fourth electronic module disposed within the second module, the fourth electronic module electrically connected to the second electronic module and to the second backplane; and
a switch/relay disposed within the second module and connected to the second backplane, the switch/relay adapted to selectively permit communication between the third electronic module and the second electronic module when there is a failure within the first electronic module.

7. The housing of claim 6, wherein first and second electronic modules are disposed within a card cage of the first module.

8. The housing of claim 6, wherein the third and fourth electronic modules are disposed within a card cage of the second module.

9. The housing of claim 6, wherein the third electronic module comprises a plurality of connectors connectable to remote equipment.

10. The housing of claim 7, wherein the second backplane is attached to the card cage.

11. The housing of claim 8, wherein the second backplane is disposed within the card cage.

12. A housing for an electronic system:
a first module comprising a first card cage;
a first backplane disposed within the first module;
first and second electronic modules disposed within the first card cage, each of the first and second electronic modules electrically connected to the first backplane;
a second module attached to the first module, the second module comprising a second backplane and a second card cage;
a third electronic module disposed within the second card cage, the third electronic module electrically connected to the first electronic module and to the second backplane;
a fourth electronic module disposed within the second card cage, the fourth electronic module electrically connected to the second electronic module and to the second backplane; and
a switch/relay disposed within the second card cage and connected to the second backplane, the switch/relay adapted to selectively permit communication between the third electronic module and the second electronic module when there is a failure within the first electronic module.

13. The housing of claim 12, wherein the second backplane is attached to the first card cage.

14. The housing-of claim 12, wherein the second backplane is disposed within the second card cage.

15. The housing of claim 12, wherein the third electronic module comprises a plurality of connectors connectable to remote equipment.

16. A method for modifying a housing containing a non-redundant cable modem termination system to add redundancy to the non-redundant cable modem termination system, the method comprising:
attaching a backplane to the housing;
attaching a card cage to the housing;
inserting a first electronic module into the card cage for electrically connecting the first electronic module to the backplane and to a first electronic module of the non-redundant cable modem termination system;
inserting a second electronic module into the card cage for electrically connecting the second electronic module to the backplane and to a second electronic module of the non-redundant cable modem termination system;
inserting a switch/relay into the card cage, the switch/relay adapted to selectively permit communication between the first electronic module and the second electronic module of the non-redundant cable modem termination system when there is a failure within the first electronic module of the non-redundant cable modem termination system.
